(19) United States
(12) Patent Application Publication
(10) Pub. No.: US 2012/0112749 A1
(43) Pub. Date: May 10, 2012

(54) APPARATUS AND METHOD FOR INCREASING SPIN RELAXATION TIMES FOR ALKALI ATOMS IN ALKALI VAPOR CELLS

(75) Inventors: Dmitry Budker, El Cerrito, CA (US); Micah Ledbetter, Oakland, CA (US); Todor Karaulanov, Los Alamos, NM (US); Mikhail V. Balabas, St. Petersburg (RU)

(73) Assignee: THE REGENTS OF THE UNIVERSITY OF CALIFORNIA, Oakland, CA (US)

(21) Appl. No.: 13/286,930

(22) Filed: Nov. 1, 2011

Related U.S. Application Data
(60) Provisional application No. 61/409,004, filed on Nov. 1, 2010.

(51) Int. Cl. G01R 33/00

(52) U.S. Cl. 324/318

(57) ABSTRACT

An atomic vapor cell apparatus and method for obtaining spin polarized vapor of alkali atoms with relaxation times in excess of one minute is provided. The interior wall of the vapor cell is coated with an alkene-based material. The preferred coatings are alkenes ranging from C18 to C30 and C20-C24 are particularly preferred. These alkene coating materials, can support approximately 1,000,000 alkali-wall collisions before depolarizing an alkali atom, an improvement by roughly a factor of 100 over traditional alkane-based coatings. Further, the method involves a combination of one or more of the following: the use of a locking device to isolate the atoms in the volume of the vapor cell from the sidearm used as a reservoir for the alkali metal vapor source, careful management of magnetic-field gradients, and the use of the spin-exchange-relaxation-free (SERF) technique for suppressing spin-exchange relaxation.

### CROSS-REFERENCE TO RELATED APPLICATIONS

This application claims priority from U.S. provisional patent application Ser. No. 61/409,004 filed on Nov. 1, 2010, which is incorporated herein by reference in its entirety.

### STATEMENT REGARDING FEDERALLY SPONSORED RESEARCH OR DEVELOPMENT

This invention was made with Government support under Grant No. N00014-05-1-0406 awarded by the Office of Naval Research, and under Grant No. PHY-0855552 awarded by the National Science Foundation. The Government has certain rights in this invention.

### INCORPORATION-BY-REFERENCE OF MATERIAL SUBMITTED ON A COMPACT DISC

Not Applicable

### BACKGROUND OF THE INVENTION

1. Field of the Invention

The present invention pertains generally to atomic vapor cells, and more particularly to method for achieving extremely long-lived polarization in alkali vapor cells with walls coated with long chain alkenes.

2. Description of Related Art

Long-lived ground-state coherences in atomic vapor cells form the basis for atomic clocks, magnetometers, quantum memory, spin-squeezing and quantum non-demolition measurements, and precision measurements of fundamental symmetries. For example, modern magnetometers have enabled significant advances in areas of low-magnetic-field nuclear magnetic resonance (NMR), magnetic resonance imaging (MRI), and medical imaging, as well as paleomagnetism, explosives detection, and ultra-sensitive tests of fundamental physics.

The sensitivity of atomic vapor cell devices is generally limited by the number of atoms and their spin coherence lifetime. The spin projection noise limited sensitivity is seen to scale as the square root of the spin relaxation time. Consequently, considerable efforts have been made to identify methods for reducing the relaxation rate of coherences between atomic states in atomic vapor cells.

Alkali metal vapor of sufficient density is normally produced inside the vapor cell by simply heating solid alkali metal within the cell. Enclosed vapors of rubidium, cesium or potassium that are typically used in atomic vapor cells can lose their atomic spins with just one collision with the wall of the vapor cell. One approach to this problem is to include a buffer gas to limit the rate of diffusion of vapor atoms to the walls of the cell. While diffusion limited relaxation times of a few seconds can be achieved by this method, it also incurs additional relaxation via alkali-buffer gas spin-destruction collisions. Furthermore, the additional buffer gas can produce undesirable broadening of optical transitions.

Another source of spin relaxation is due to the exchange of atoms between the vapor phase and the metal sample in the stem of the vapor cell known as the reservoir effect.

Later, it was discovered that the atomic polarization relaxed at a much slower rate in vapor cells that had walls that were coated with paraffin (CₙH₂ₙ₊₂). Conventional paraffin coatings are formed from long chain alkane molecules such as tetracontane (n=40). Anti-relaxation coatings of paraffin in atomic vapor cells allow ground-state coherent spin states to survive many collisions with the cell walls and eliminated the need for the buffer gas. It was found that atomic vapor cells coated with high quality paraffin enabled polarized alkali atoms to bounce off of the cell walls as many as 10,000 times before they depolarized. However, this is the upper limit for paraffin. Paraffin-coated cells also provide narrow hyperfine resonances. Many technologies that are based on cells containing alkali-metal atomic vapor now benefit from the use of paraffin anti-relaxation surface coatings in order to preserve atomic spin polarization.

Operation of the vapor cell at higher temperatures is beneficial for many devices because it increases the saturated vapor pressure of the alkali atoms and provides greater atomic density and better sensitivity. However, the performance of paraffin coatings quickly degrades at temperatures above 60-80° C. and it may not be available as a coating in some settings.

Recent magnetometers that have achieved ultra-high sensitivity better than 1 fT/pHz need to operate at high vapor densities and have comparatively high operating temperatures (T>100° C. for cesium vapor and T>150° C. for potassium vapor) that prevent the use of paraffin coatings. In addition, paraffin does not survive the elevated temperatures required by the anodic bonding process used in the production of microfabricated vapor cells.

The latest efforts at developing alternatives to paraffin have mainly focused on certain silane coatings that resemble paraffin, containing a long chain of hydrocarbons but also a silicon head group that chemically binds to the glass surface. Such materials do not melt and remain attached to the glass surface at relatively high temperatures, enabling them to function as anti-relaxation coatings at much higher temperatures than paraffin. In particular, a multilayer coating of octadecyltrichlorosilane [OTS, CH₃(CH₂)₁₇SiCl₃] has been observed to allow from hundreds up to 2100 bounces with the cell walls and can operate in the presence of potassium and rubidium vapor up to about 170° C. However, the quality of such coatings with respect to preserving alkali polarization is highly variable, even between cells coated in the same batch, and remains significantly worse than that achievable with paraffin.

Accordingly, there is a need for surface coatings with high temperature stability for use with high-density alkali vapor cells. High-temperature coatings also allow use of potassium and sodium vapor, which have lower vapor pressures compared to rubidium and cesium at any given temperature. There is also a need for an apparatus and method that can efficiently increase the spin relaxation times of alkali atoms in atomic vapor cells at suitable temperatures. The present invention satisfies these needs as well as others and is generally an improvement over the art.

### BRIEF SUMMARY OF THE INVENTION

The invention is directed to an apparatus and method for producing long relaxation time atomic vapor polarization and an atomic vapor cell with an anti-relaxation coating of an alkene-based material on the inner walls that can be used in any technology that is based on atomic spin polarization and use cells containing vapor such as alkali-metal vapor.

The atomic vapor cell is used in many different technologies. The typical cell contains a bulb with a stem and a side branch containing a source of atomic vapor such as an alkali metal. The vapor is typically generated by heating a solid alkali metal in a reservoir and collecting the vapor in the bulb.

In the case of a magnetometer, the vapor is usually polarized by a pump laser and probed with an orthogonal probe laser and analyzer. Sensitivity of the device is dependent, in part, on the lifetime of the spins. However, relaxation of the spin polarization can occur through atom-bulb wall interactions, atom-atom interactions and atom-vapor source interactions that produce spin lifetimes of a few seconds or less.

Polarization lifetimes of atomic populations and coherences in excess of 60 seconds in alkali vapor cells with inner walls coated with an alkene material are illustrated. Long relaxation times of spin polarized vapor of alkali atoms can be achieved with atomic vapor cells that have a bulb with inner walls that have been coated with an alkene-based material. The “anti-relaxation” materials of the invention can support approximately 1,000,000 alkali-wall collisions before depolarizing an alkali atom, an improvement by roughly a factor of 100 over traditional alkane-based coatings. Relaxation times are also lengthened by using a combination of one or more of the following: the use of a locking device to isolate the atoms in the volume of the vapor cell from the sidearm used as a reservoir for the alkali metal, careful management of magnetic-filed gradients, and the appropriate use of the spin-exchange-relaxation-free (SERF) techniques for suppressing spin-exchange relaxation.

Although SERF magnetometer is used as an example, the coating will also benefit alternative magnetometric configurations, such as nonlinear magneto-optical rotation (NMOR) or variants thereof, where a single laser beam can be used to pump and probe atomic alignment; or the original Bell-Bloom technique where absorption of the modulated circularly polarized light is monitored synchronously.

The preferred bulb anti-relaxation coating is formed from long chain alkenes within the range of C18 to C30 that have at least one C═C double bond and as many as three. The long chain (C18-C30) Alpha-Olefins are preferred and the Alpha-Olefin fraction C20-24 alkenes are particularly preferred. While the Alpha-Olefins are preferred, the double bond in the second or third position may also be used.

Polarization lifetimes of atomic populations and coherences in excess of 60 seconds in alkali vapor cells with inner walls coated with an alkene material are demonstrated. This represents two orders of magnitude improvement over the best paraffin coatings known in the art. Such anti-relaxation properties will likely lead to substantial improvements in atomic clocks, magnetometers, quantum memory, and enable sensitive studies of collisional effects and precision measurements of fundamental symmetries.

According to one aspect of the invention, a method for reducing the relaxation rate of polarized vapor atoms is provided that decreases relaxation due to atom-wall interactions, atom-atom interactions and atom-vapor source interactions.

Another aspect of the invention is to provide an atomic vapor cell wall coating that will preserve atomic spin polarization even after many impacts with the coating.

Another aspect of the invention is to provide an atomic vapor cell that isolates the vapor from the source of vapor and improving the rate of relaxation of the polarized atoms.

Further aspects of the invention will be brought out in the following portions of the specification, wherein the detailed description is for the purpose of fully disclosing preferred embodiments of the invention without placing limitations thereon.

### BRIEF DESCRIPTION OF THE SEVERAL VIEWS OF THE DRAWING(S)

The invention will be more fully understood by reference to the following drawings which are for illustrative purposes only:

FIG. 1 is a schematic diagram of magnetometer set up according to one embodiment of the invention.

FIG. 2 is a front side view of one atomic vapor cell with a bulb, stem and branch holding an alkali metal reservoir for the production of alkali vapor and a slidable barrier closing off the bulb from the reservoir of bulk alkali metal as used in the embodiment of FIG. 1.

FIG. 3 is a flow diagram of one method for achieving long spin relaxation times for alkali atoms with alkene coated atomic vapor cells.

FIG. 4 is a graph of the transverse relaxation rate as a function of magnetic field for three pump power values.

FIG. 5 is a graph of experimental measurements of spin broadening verses effective geomagnetic ratio for a range of pump power values.

### DETAILED DESCRIPTION OF THE INVENTION

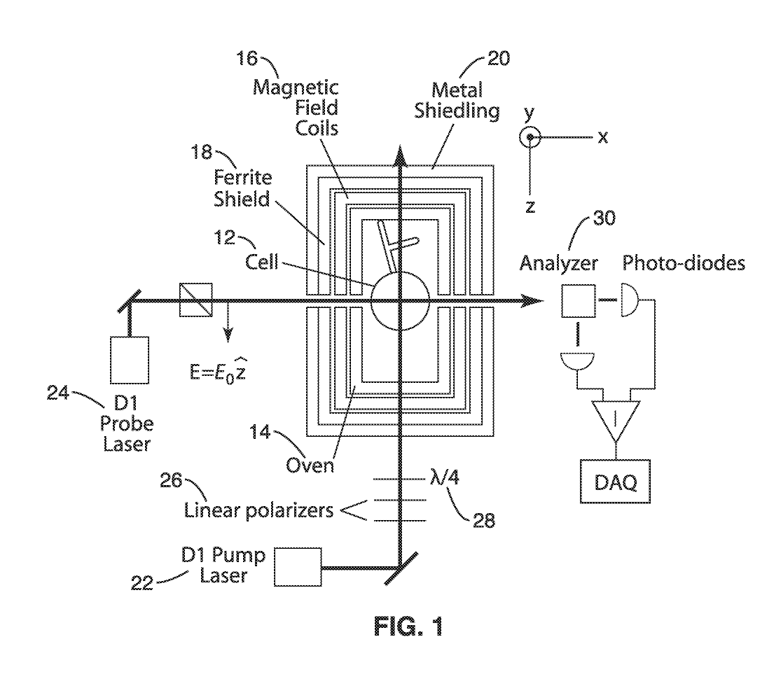

Referring more specifically to the drawings, for illustrative purposes the present invention is embodied in the apparatus and method generally shown in FIG. 1 through FIG. 5. It will be appreciated that the apparatus may vary as to configuration and as to details of the parts, and that the methods may vary as to the specific steps and sequence, without departing from the basic concepts as disclosed herein. By way of example and not of limitation, the apparatus of the present invention generally comprises an atomic vapor cell with inner walls coated with an anti-relaxation coating of an alkene.

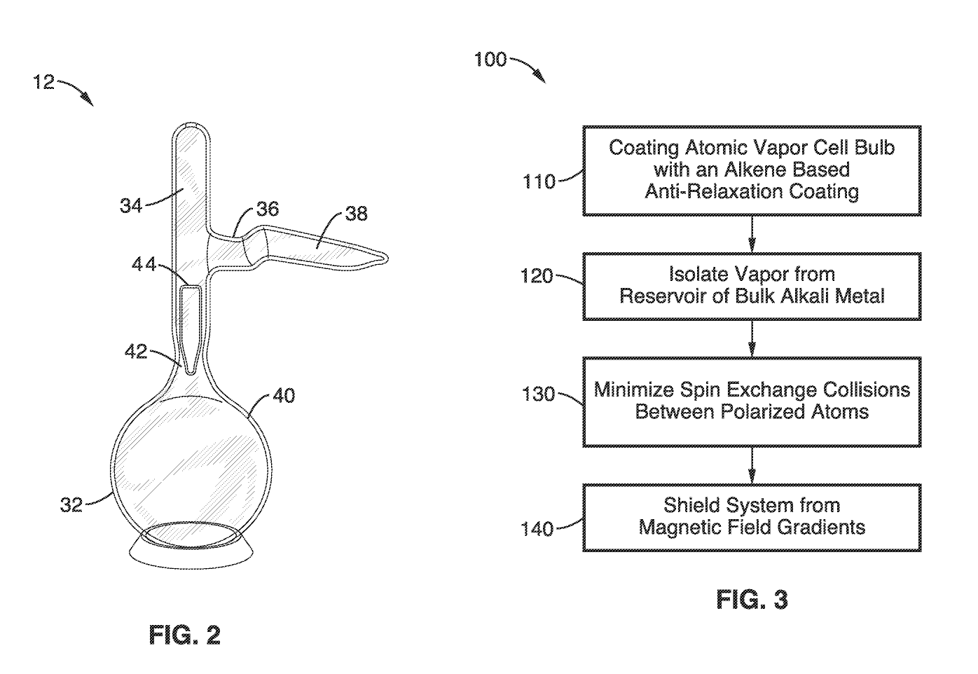

Turning now to FIG. 1 through FIG. 2, one embodiment of the invention 10 is schematically shown. The invention with a vapor cell 12 is adapted for use in the context of a magnetometer in FIG. 1, however it will be understood that the invention can be used in any setting that uses atomic vapor cells and benefits from minimal decoherence of spin states.

The atomic vapor cell based magnetometer illustrated in FIG. 1 is configured for Spin-exchange relaxation-free (SERF) atomic magnetometery to demonstrate the anti-relaxation properties of the alkene-based coating. The apparatus of FIG. 1 has a vapor cell 12 placed within a heating element or oven 14. In one embodiment, heated or cooled air is passed over the vapor cell 12 to control the temperature within the cell.

One or more magnetic field coils 16 surrounding the cell are provided within a ferrite shield 18 and preferably one or more mu-metal shielding layers 20 to eliminate random external magnetic fields. In one embodiment, a solenoid and sets of coils are present to produce homogeneous magnetic fields and a transverse radio frequency fields for some applications where the decoherence rate and Zeeman frequencies are determined by sweeping an rf frequency through the Zeeman reference that produces a drop in the transmission spectrum.

There are many possible ways to configure an atomic magnetometer. In the implementation depicted in FIG. 1, the pump beam is circularly polarized and tuned to the center of the D1 transition. An orthogonal probe beam is used to detect the precession using optical rotation of linearly polarized light. Accordingly, a pump laser 22 with linear polarizers 26 and a quarter wave plate 28 directs a circularly polarized pump beam to cell 12 within the enclosure to polarize the alkali vapor in the vapor cell 12 as shown in the embodiment of FIG. 1. A probe laser 22 is configured to direct a linearly polarized probe beam through the cell 12 to analyzer 30. If the magnetic fields are sufficiently small that the Larmor precession frequency is small compared to the rate of spin-exchange, the configuration of orthogonal pump (circularly polarized) and probe (linearly polarized) beams would be known in the literature as spin-exchange relaxation-free. It is important to note that alternative configurations, for example, nonlinear magneto-optical rotation or versions thereof that employ modulated light, would also benefit from the new coating material described herein.

In the configuration shown in FIG. 1, an atomic magnetometer has a vapor of atoms (typically alkali metal atoms) that is contained in a glass cell 12. The atoms are polarized by an appropriate light source such as a circularly polarized laser 22, tuned to the center of an atomic absorption line of the atom. In a magnetic field transverse to the spin polarization, the spin polarization of the alkali polarization precesses about the magnetic field. The precession frequency then serves as a measure of the magnetic field. Spin precession of the vapor atoms can be monitored by a linearly polarized probe beam from probe laser 24, tuned off resonance with analyzer 30.

In most cases, fundamentally limiting the sensitivity of an atomic magnetometer is spin-projection noise:

$$δ B = \frac{1}{γ} \frac{1}{\sqrt{{NT}_{2} t}}$$

where γ is the gyromagnetic ratio, N is the number of atoms participating in the measurement, T₂ is the transverse relaxation time, and t is the measurement time. Since δB is the minimum detectable magnetic field change, it is desirable to work with the largest possible values of N and T₂. There are also several contributions to spin relaxation. In an uncoated cell, the largest source of relaxation comes from alkali-wall collisions. The new coating material described herein, Alpha-Olefin C20-24 suppresses this relaxation by a factor of a million. The next largest source of relaxation are alkali spin-exchange collisions, which can be eliminated by operating in the spin-exchange relaxation free regime in a near zero magnetic field. Finally, spin-destruction collisions, either between alkali atoms or with the alkali reservoir are typically the smallest source of relaxation. Alkali-reservoir collisions are mitigated by isolating the vapor from the bulk alkali metal with a conventional valve or the locking bullet barrier 44 shown in FIG. 2.

A conventional vapor cell 12 with a spherical bulb is shown in FIG. 2. While a spherical bulb is typical, the coatings of the present invention can also be applied to vapor cells of any shape and size. The typical atomic vapor cell 12 is a glass vessel with a bulb 32 that has a hollow cylindrical stem 34. It is preferred that bulb 32 have one or more uniform coatings of an alkene based anti-relaxation coating 40 on the interior surface of the bulb. The coating 40 preferably extends to the neck 42 of stem 34 so that there are no exposed glass surfaces in the interior of bulb 32 of the vessel.

Stem 34 has at least one branch 36 that has an alkali metal reservoir 38 in the embodiment shown in FIG. 2. Alkali metal vapor of sufficient density is obtained by simply heating solid alkali metal that has been placed inside the reservoir 38 of the vapor cell 12 and sealed. The alkali vapor from the bulk metal passes through the interior of branch 36 and down stem 34 to collect in the bulb 32 of the vapor cell 12.

Exchange of polarized vapor atoms present in the bulb 32 of the cell 12 and the stem 34 with the heated alkali metal in the metal reservoir 38 of FIG. 2 can also produce rapid relaxation of the spins and should be mitigated. This can be accomplished by employing a “lockable stem” which provides a coated barrier 44 to reduce the rate of exchange between the bulb and the stem. The barrier 44 is a bullet shaped cylindrical or spherical structure that is sized to slide in the interior of stem 34 and seat in neck 42 after the vapor is formed and contained in bulb 32. The barrier 44 prevents movement of the polarized vapor from the bulb 32 to the stem 34 and reservoir 38. In addition, the barrier 44 prevents entry of particles of alkali metal into the bulb 32 because the metal can interact with the coating 40 and damage it. The barrier 44 can also be a valve placed in the stem 34 or the branch 36 containing the reservoir 38 to isolate the vapor.

Many different techniques for coating the bulbs of vapor cells have been developed for paraffin and other vapor cell coatings. Generally, the coating 40 is applied after evacuating and cleaning the interior of the cell 12. The bulk coating material is melted and partly evaporated by raising the temperature of the bulb to approximately 120° C. to 300° C. and then cooling to room temperature so that the coating condenses on to the interior walls of the bulb to form the coating 40. The temperature is selected to prepare a coating with desired thickness. The process can be repeated to improve coating uniformity if spots appear in the coating 40. Once the coating 40 has been applied, the solid Rb or other atom vapor source can be placed in the metal reservoir 38 and the reservoir 38 sealed.

The coating 40 is preferably made from long chain alkenes typically ranging from C18 to C30 depending on the system and selected alkali metal vapor used in the vapor cell. Alpha-Olefins of C18-C30 are preferred but alkenes with the double bond in the second (vinylidene) or third position may also be used. A coating 40 formed from Alpha-Olefin fraction C20-24, indicating an alkene with a mixture of molecules with 20-24 carbon atoms, is particularly preferred. Coatings of C₁₈H₃₆ and C₁₉H₃₈ are also preferred.

A preliminary investigation of the Alpha-Olefin fraction C30 found that the anti-relaxation properties were not as good as the lighter fraction, supporting on the order of 10,000 bounces, however the coating appears to be more robust with respect to temperature than paraffin. Experiments revealed that the properties of the C30 coating appear to be unchanged at temperatures as high as 120° C. This enables one to work with extremely optically thick vapors, which may be advantageous in magnetometric schemes involving quantum non-demolition measurements.

The upper end of the range of alkenes that can be used for coating 40 is the coating preparation temperature and the number of C═C bonds that will produce a suitable anti-relaxation function for the coating. The lower end of the range of preferred suitable alkene molecules is determined by the melting point of the coating material (i.e., 18° C. for C₁₈H₃₆).

The anti-relaxation capability of a coating 40 containing C=C double bonds was unexpected because unsaturated bonds increase the polarity of the surface of the coatings. It has been assumed in the art that effective anti-relaxation coatings require low polarizability to keep alkali atom residence times on the coating short.

Coherence lifetimes on the order of 1 minute in a 3 cm diameter atomic vapor cell, corresponding to about 10⁶ polarization preserving bounces, have been obtained with the apparatus and methods of the present invention. This appears to be the narrowest electron paramagnetic resonance ever observed to date.

Turning now to FIG. 3, a flow diagram of one embodiment of the method 100 for achieving long spin relaxation times for alkali atoms in a vapor cell is described. At block 110, an atomic vapor cell is provided with an alkene based anti-relaxation coating. The alkene coating is preferably formed from alkenes ranging from C18 to C30. An alkene coating such as one derived from Alpha Olefin Fraction C20-24 from Chevron Phillips (CAS Number 93924-10-8) is particularly preferred. The function of this coating is to reduce atom-wall collisions that depolarize the spins. The effectiveness of saturated long chain coatings as anti-relaxation coatings was unexpected. The coatings are also stable in temperatures at and above room temperature making them useful in many different vapor cell applications.

The polarized alkali metal vapor is isolated from the source of the vapor at block 120 of FIG. 3. This isolation is important because contact of polarized vapor atoms with the bulk metal in the reservoir leads to rapid relaxation times. This can be accomplished with the use of a “lockable stem” or valve that provides a coated barrier to reduce the rate of exchange between the bulb and the uncoated stem and reservoir.

The atom-atom spin exchange is minimized at block 130 of FIG. 3. Another important step in realizing long spin lifetimes is to conduct work in magnetic fields such that the Larmor precession frequency is small compared to the spin-exchange rate, and to optically pump the alkali vapor with circularly polarized light. This largely eliminates relaxation due to spin-exchange collisions and is called the spin-exchange relaxation-free (SERF) regime. SERF magnetometers presently hold the record for magnetic field sensitivity of any device, but these devices usually require operation at temperatures in excess of 150° C. The alkene coating described here enables operation of such a magnetometer in a room temperature environment, dramatically expanding its useful range of applications, especially where low power consumption is important. The invention provides a room temperature atomic magnetometer operating in the SERF regime in one embodiment. The technique described here for reducing atom-wall relaxation can also be applied to other magnetometric configurations, for example in nonlinear magneto-optical rotation. Other techniques can be used to reduce the atom-atom spin exchange collisions as well.

Finally, at block 140 gradients of the magnetic field are another source of relaxation, so care must be taken to minimize them.

The invention may be better understood with reference to the accompanying examples, which are intended for purposes of illustration only and should not be construed as in any sense limiting the scope of the present invention as defined in the claims appended hereto.

### Example 1

In order to demonstrate the longevity of Zeeman populations and coherences in alkali-metal vapor cells with inner walls coated with an alkene material, a room temperature magnetometer with cells coated with 1-nonadecene (CH₂—CH(CH₂)₁₆—CH₂) was used in the context of spin-exchange relaxation-free (SERF) magnetometry, a regime inaccessible with conventional paraffin coating materials. Coherences in excess of 60 seconds were observed with 3 cm diameter cells corresponding to approximately 1,000,000 polarization-preserving alkali-wall collisions. This represents approximately 2 orders of magnitude improvement over the best paraffin coatings.

Since the exchange of atoms between the bulb of the cell and the stem with the Rb reservoir can produce rapid relaxation, a “lockable stem” was employed that provided a coated barrier to reduce the rate of exchange between the vapor in the bulb and the stem as shown in FIG. 2. To investigate the alkene-based coating carefully, three Rb vapor cells with lockable stems were prepared. Cells C1 and C2 had natural-abundance Rb and non-ideal locks and cell C3 had ⁸⁷Rb and a “precision ground” lock. The initial material for the coating preparation was Alpha Olefin Fraction C20-24 from Chevron Phillips (CAS Number 93924-10-8). A light fraction of the material was removed through vacuum distillation at 80° C. The remainder was used as the coating material. Coatings for C1, C2 and C3 were prepared at 175° C. and cured at 70° C. for several hours.

To perform the analysis of each coated cell, the cell was placed inside four layers of mu-metal and one layer of ferrite shielding. A circularly polarized pump beam, propagating in the z direction, tuned near the F=2→F′ D1 transitions of ⁸⁵Rb, optically pumped the alkali spins. Spin precession was monitored via optical rotation of linearly polarized probe light, propagating in the x direction, tuned about 1.5 GHz to the blue of the F=3→F′ D1 transitions of ⁸⁵Rb. Optical rotation, scaling roughly as the inverse of detuning, was dominated by ⁸⁵Rb, however there was some contribution from ⁸⁷Rb. Typical probe power was ≈2 μW, although much higher probe power could have been be used without incurring substantial additional broadening since the probe was tuned far off resonance. Pump power ranged from about 0 μW to about 2 μW. Most of the measurements were performed at a temperature of 30° C. where the Rb vapor density was n≈1.5×10¹⁰ cm⁻³, measured by transmission of a weak probe beam. The orientation of the cell could be manipulated from outside the magnetic shields so that the lock could be opened and closed without opening the shields. With the lock open, polarization lifetimes of approximately 3 seconds were observed, much shorter than seen with the lock closed.

Using the apparatus shown schematically in FIG. 1, the relaxation of both the longitudinal and transverse (with respect to magnetic field) components of spin polarization was also investigated. Longitudinal relaxation was measured by first applying a magnetic field parallel to the pump beam, and then adiabatically rotating the magnetic field into the direction of the probe beam, and subsequently monitoring optical rotation of the probe as the longitudinal polarization decayed.

To investigate transverse relaxation, the transient response of the alkali spins to a non-adiabatic change in the magnetic field was observed by, either (1) pumping the spins in zero magnetic field and applying a step in B_{y}, or (2) by pumping the spins in a finite bias magnetic field B_{z} and then applying a short pulse of magnetic field Bₓ, similar to RF excitation pulses in nuclear magnetic resonance. High field (10-20 G) measurements of the longitudinal relaxation time were also conducted.

The decay of longitudinal polarization was well described by two exponentials with the observed fast and slow time constants T_{1f}=8 s and T₁ₛ=53 s, respectively. Such biexponential decays arise from several competing processes of electron spin-destruction collisions with the cell walls, residual relaxation due to collisions with the reservoir, and alkali-alkali spin-exchange collisions.

Transient responses to a step in the magnetic field B_{y}≈0.2 μG after pumping at a zero magnetic field were also observed. In such low magnetic fields, the transient response is described by an oscillating signal with a single frequency and a return to steady state, with fast and slow decays characterized by lifetimes T_{2f} and T₂ₛ observed to be T_{2f}=13 s and T₂ₛ=77 s. The presence of only a single frequency oscillation occurred because the two isotopes “lock” together in the SERF regime. In larger magnetic fields, the appearance of two frequencies corresponding to free precession of either isotope in the absence of spin-exchange collisions is seen.

The effects of the spin exchange in a low-density vapor in very low magnetic fields were also evaluated. When the Larmor precession frequency is small compared to the spin-exchange rate 1/Tₑₓ=nσₑₓv (where (n is the number density, σₑₓ=1.9×10⁻¹⁴ cm² is the spin-exchange cross section for Rb, and v is the mean relative thermal velocity), the spin-exchange collisions produce relaxation that is quadratic in the magnetic field and modifies the effective gyromagnetic ratio, both of which depend on the degree of spin polarization.

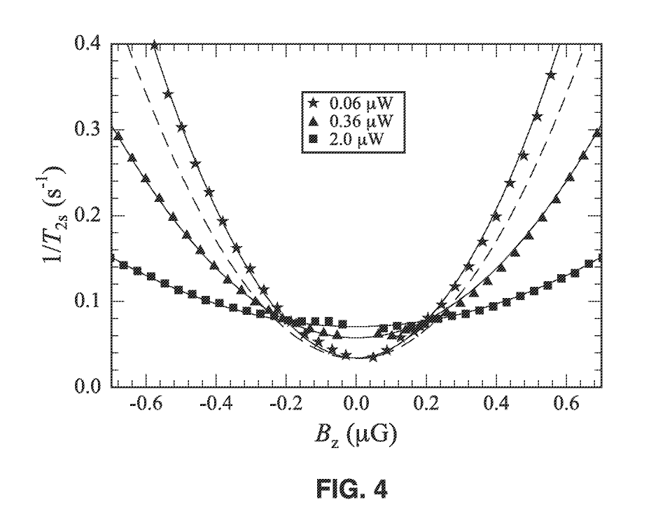

The dependence of the magnetic-field on the transverse relaxation rate, 1/T₂ₛ, for several pump powers was observed. Transverse relaxation rate as a function of magnetic field for pump power values of 0.06 μW, 0.36 μW and 2.0 μW is shown in FIG. 4. The dashed curve in FIG. 4 is the expected relaxation rate in the low polarization limit for a vapor of pure ⁸⁵Rb (I=5/2) given by the following equation, with Tₑₓ determined by transmission measurements of the density. For a single isotope with a spin-temperature distribution and low polarization, spin-exchange relaxation is given by the following equation:

$${Γ}_{SE} = {ω}_{0}^{2} {T}_{ex} \frac{{q}_{0}^{2} - {( 2 I + 1 )}^{2}}{{2}_{q 0}} ,$$

where ω₀=gₛμ_{B}B/q₀ , I is the nuclear spin, and q₀=[I(I+1)+S(S+1)]/S(S+1) is the nuclear slowing-down factor. For these data, transverse coherences were produced by applying a short (0.2 s) pulse of magnetic field in the x direction in the presence of a static field B_{z}. Relaxation was seen to deviate from the quadratic behavior seen in FIG. 4 as the magnetic field was increased, reaching an asymptotic level of 1/T₂ₛ≈3 s⁻¹ at≈1 mG. At low magnetic field, increasing pump power produced power broadening, however, at higher magnetic fields, high pump power reduced spin-exchange relaxation by preferentially populating the stretched state, which is immune to spin-exchange relaxation. The gyromagnetic ratio also varies significantly with pump power.

Accordingly, the alkene based coating of the inner walls of a vapor cell and the minimization of depolarization events permits the production of spin polarized vapor of alkali atoms with relaxation times on the order of one minute.

### Example 2

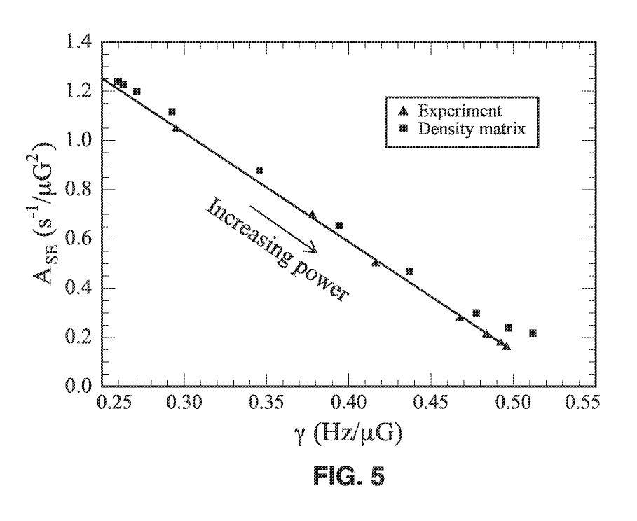

To further illustrate the method for achieving long spin relaxation times in an alkene coated atomic vapor cell, numerical calculations were performed for comparison with experimental results from the apparatus that was constructed according the general schematic shown in FIG. 1. In order to compare the experimental results with the theoretical calculations it was convenient to plot the measured spin-exchange broadening A_{SE} as a function of the effective gyromagnetic ratio γ, shown as triangles in FIG. 5. It can be seen that there is a linear relationship between the spin-exchange broadening and effective gyromagnetic ratio parameters, as indicated by the linear fit overlaying the data. It is also worth noting that, in these measurements, spin-exchange broadening approaches an asymptotic value of about 0.2 s⁻¹/μG² at high power due to the presence of two isotopes, as can be seen by the clustering of data points at high light power, despite the increasing size of the light power steps. In an isotopically pure vapor, relaxation due to spin-exchange collisions could be largely eliminated at high pump power by hyperfine pumping.

To investigate the effects of spin-exchange collisions, numerical simulations were performed for comparison with the results of Example 1. The contributions to the evolution of the ground state density matrix ρⱼ for isotope j due to hyperfine splitting, Zeeman splitting, optical pumping, spin-destruction, and spin-exchange are, respectively as follows:

$$\frac{d {ρ}_{j}}{d t} = \frac{{a}_{j}}{i ℏ} [ {I}_{j} \cdot {S}_{j} , {ρ}_{j} ] + \frac{{g}_{s} {μ}_{B}}{i ℏ} [ B \cdot {S}_{j} , {ρ}_{j} ] + R [ {φ}_{85} ( 1 + 2 z \cdot {S}_{85} ) - {ρ}_{j} ] + \frac{{φ}_{j} - {ρ}_{j}}{{T}_{sd}} + {\sum }_{k} \frac{{φ}_{j} ( 1 + 4 〈 {S}_{k} 〉 \cdot {S}_{j} ) - {ρ}_{j}}{{T}_{ex , jk}} .$$

Here aⱼ is the hyperfine constant, Iⱼ is the nuclear spin, gₛ is the Landé factor for the electron, μ_{B} is the Bohr magneton, R is the optical pumping rate for ⁸⁵Rb (as there is no optical pumping of ⁸⁷Rb since the pump light is resonant only with ⁸⁵Rb transitions), and φⱼ=ρⱼ/4+Sⱼ·ρⱼSⱼ is the purely nuclear part of the density matrix. The spin-destruction rate T_{sd} was determined from measurements of T₁, and the spin-exchange rates T_{ex,jk} were determined by the measured alkali density and the known cell cross-sections.

The transient response to a pulse of magnetic field in the y direction and subsequent precession around a static field in the z direction is determined by numerically integrating preceding equation starting from a spin-temperature distribution along the z axis. The x component of electron spin polarization was extracted, weighted by isotopic abundance ηⱼ, [symbol] Sₓ [symbol] =η₈₅ [symbol] S_{x,85} [symbol] +η₈₇ [symbol] S_{x,87} [symbol] , a reasonable approximation of the experimental observable, and then fit into a decaying sinusoid. The squares in FIG. 5 show the results of simulations. Experimental results and the simulation are in good agreement for low light power, although there is some small systematic offset, which is attributed to uncertainty in the alkali vapor density. At higher light power, the simulation deviates from experiment, presumably because the optical pumping term in the equation is correct in the limit of unresolved hyperfine structure, and therefore cannot account for hyperfine pumping present in the experiment.

### Example 3

To demonstrate the adaptability and versatility of the coated atomic vapor cell for use in different types of magnetometry, a magnetometer was constructed for nonlinear magneto-optical rotation (FM-NMOR) magnetometry for evaluation. A typical NMOR apparatus includes an atomic vapor cell and two lasers, one for pumping the optical transitions of the atomic vapor of an alkali metal, in this case rubidium, and the other for probing the optical vapor, by differential polarimetry to detect the rotation of polarization. Electronics amplify the differential polarization signal and filter out noise, then condition the phase and amplitude for feedback to the pump laser. With the proper feedback, the magnetometer self-oscillates at a frequency that is a multiple of the Larmor frequency (or its harmonics). Counting the oscillation frequency over some period of time provides an estimate of the average magnetic field during that time. To enhance sensitivity, the atomic sample is held in a glass bulb whose inner surface has been specially coated to suppress relaxation of the direction and magnitude of the atomic spin. Additional atomic vapor cells may also be used for monitoring and stabilizing the laser wavelengths.

The self-oscillating signal was routed to a counter, which showed better than 1 Hz stability. Digitization and analysis of the self oscillation signal yielded a power spectral distribution of magnetic signals, with a minimum noise of 2 to 3 pT/Hz^{1/2}.

Accordingly, the alkene coating of the present invention has been shown to support up to 10⁶ alkali-wall collisions before depolarizing the alkali spins when all other sources of relaxation are properly mitigated. This represents an improvement by nearly a factor of 100 over traditional coatings. For example, cells employing such coatings can enable operation of a SERF magnetometer in a room temperature environment, dramatically expanding the scope of applications for such magnetometers.

In addition to magnetometry, anti-relaxation coatings can be used in a number of other contexts in both pure and applied research. As were outlined here, alkene coatings can be used to study the effects of spin-exchange collisions in very low density environments, and may be of use for investigating more subtle atom-atom collisions. Alkali vapor cells utilizing such coatings may also dramatically improve the performance of atomic clocks, depending on the nature of the hyperfine shifts associated with atom-wall collisions. Alkene coated cells may greatly enhance the lifetime of quantum memory applications or the storage time of light in “slow-light” experiments. In the context of geophysical measurements, extremely narrow lines can reduce orientation dependent “heading errors” due to the non-linear Zeeman effect, a significant issue in geomagnetic surveying. While spin-exchange relaxation is difficult to completely eliminate at high fields, the use of only a single isotope and hyperfine pumping may reduce such relaxation considerably.

From the discussion above it will be appreciated that the invention can be embodied in various ways, including the following:

1. An atomic vapor cell apparatus embodiment comprising a bulb with an interior surface and an exterior surface with the interior surface coated with a long chain alkene and alkali-metal vapor disposed within the interior of the bulb.

2. The apparatus of embodiment 1, wherein the long chain alkene comprises an alkene with a length of between 18 carbons and 30 carbons.

3. The apparatus of embodiment 1, wherein the long chain alkene comprises an alkene with a length of between 20 carbons and 24 carbons.

4. The apparatus of embodiment 1, wherein the long chain alkene comprises an Alpha Olefin with a length of between 18 carbons and 30 carbons.

5. The apparatus of embodiment 1, wherein the long chain alkene comprises an alkene derived from the Alpha Olefin Fraction C20-24.

6. The apparatus of embodiment 1, wherein the bulb further comprises a reservoir configured to retain an alkali metal; a hollow stem with a central bore open to the interior of the bulb and to the reservoir; and a valve between the reservoir and the bulb; wherein alkali metal vapor present in the bulb is isolated from the reservoir of alkali metal by the valve.

7. The apparatus of embodiment 6, wherein the valve of said bulb comprises a cylindrical glass lock slideably disposed within the hollow stem between the reservoir and the bulb.

8. The apparatus of embodiment 1, further comprising a shielded container with two pairs of orthogonal access ports configured to enclose the bulb, the container comprising at least one exterior metal shield; a ferrite shield; magnetic field coils; and at least one heating element; wherein the bulb is shielded from magnetic fields localized around the container.

9. The apparatus of embodiment 8, further comprising a pump laser directed at the bulb through a first pair laser access ports in the container; a probe laser directed at the bulb through a second pair of laser access ports; and an analyzer configured to receive and analyze probe laser light that has been transmitted through the bulb.

10. A method for increasing relaxation time while obtaining spin polarized vapor of alkali atoms, wherein a vapor cell having an inner wall is used, the method comprising coating the inner wall of the vapor cell with an alkene-based material.

11. The method of embodiment 10, further comprising using a locking device to isolate atoms in the volume of the vapor cell from a sidearm used as a reservoir for the alkali metal.

12. The method of embodiment 10, further comprising managing magnetic-field gradients.

13. The method of embodiment 10, further comprising using the spin-exchange-relaxation-free (SERF) technique for suppressing spin-exchange relaxation.

14. The method of embodiment 10, further comprising isolating polarized atoms in the volume of the vapor cell from a sidearm used as a reservoir for the alkali metal; managing magnetic-field gradients; and using the spin-exchange-relaxation-free (SERF) technique for suppressing spin-exchange relaxation.

15. The method of embodiment 10, wherein the alkene based material comprises an alkene with a length of between 18 carbons and 30 carbons.

16. The method of embodiment 10, wherein the alkene based material comprises an alkene with a length of between 20 carbons and 24 carbons.

17. The method of embodiment 10, wherein the alkene based material comprises an alkene derived from the Alpha Olefin Fraction C20-24.

18. An improved atomic vapor cell having an inner wall, the improvement comprising coating the inner wall with an alkene-based material.

19. The improved vapor cell of embodiment 18, wherein the alkene-based material is a linear Alpha-Olefin ranging from 18 carbons to 30 carbons in length.

20. The improved vapor cell of embodiment 18, wherein the alkene-based material is derived from the Alpha Olefin Fraction C20-24.

Although the description above contains many details, these should not be construed as limiting the scope of the invention but as merely providing illustrations of some of the presently preferred embodiments of this invention. Therefore, it will be appreciated that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. 112, sixth paragraph, unless the element is expressly recited using the phrase “means for.”

What is claimed is:

1. An atomic vapor cell apparatus, comprising:
a bulb with an interior surface and an exterior surface, the interior surface coated with a long chain alkene; and
alkali-metal vapor disposed within the interior of the bulb.

2. An apparatus as recited in claim 1, wherein said long chain alkene comprises an alkene with a length of between 18 carbons and 30 carbons.

3. An apparatus as recited in claim 1, wherein said long chain alkene comprises an alkene with a length of between 20 carbons and 24 carbons.

4. An apparatus as recited in claim 1, wherein said long chain alkene comprises an Alpha Olefin with a length of between 18 carbons and 30 carbons.

5. An apparatus as recited in claim 1, wherein said long chain alkene comprises an alkene derived from the Alpha Olefin Fraction C20-24.

6. An apparatus as recited in claim 1, wherein said bulb further comprises:
a reservoir configured to retain an alkali metal;
a hollow stem with a central bore open to the interior of the bulb and to the reservoir; and
a valve between the reservoir and the bulb;
wherein alkali metal vapor present in the bulb is isolated from the reservoir of alkali metal by the valve.

7. An apparatus as recited in claim 6, wherein the valve of said bulb comprises a cylindrical glass lock slideably disposed within the hollow stem between the reservoir and the bulb.

8. An apparatus as recited in claim 1, further comprising a shielded container with two pairs of orthogonal access ports configured to enclose the bulb, the container comprising:
at least one exterior metal shield;
a ferrite shield;
magnetic field coils; and
at least one heating element;
wherein the bulb is shielded from magnetic fields localized around the container.

9. An apparatus as recited in claim 8, further comprising:
a pump laser directed at the bulb through a first pair laser access ports in the container;
a probe laser directed at the bulb through a second pair of laser access ports; and
an analyzer configured to receive and analyze probe laser light that has been transmitted through the bulb.

10. A method for increasing relaxation time while obtaining spin polarized vapor of alkali atoms, wherein a vapor cell having an inner wall is used, the method comprising:
coating the inner wall of the vapor cell with an alkene-based material.

11. The method of claim 10, further comprising using a locking device to isolate atoms in the volume of the vapor cell from a sidearm used as a reservoir for the alkali metal.

12. The method of claim 10, further comprising managing magnetic-field gradients.

13. The method of claim 10, further comprising using the spin-exchange-relaxation-free (SERF) technique for suppressing spin-exchange relaxation.

14. The method of claim 10, further comprising:
isolating polarized atoms in the volume of the vapor cell from a sidearm used as a reservoir for the alkali metal;
managing magnetic-field gradients; and
using the spin-exchange-relaxation-free (SERF) technique for suppressing spin-exchange relaxation.

15. The method of claim 10, wherein said alkene based material comprises an alkene with a length of between 18 carbons and 30 carbons.

16. The method of claim 10, wherein said alkene based material comprises an alkene with a length of between 20 carbons and 24 carbons.

17. The method of claim 10, wherein said alkene based material comprises an alkene derived from the Alpha Olefin Fraction C20-24.

18. An improved atomic vapor cell, said cell having an inner wall, the improvement comprising coating the inner wall with an alkene-based material.

19. The improved vapor cell of claim 18, wherein the alkene-based material is a linear Alpha-Olefin ranging from 18 carbons to 30 carbons in length.

20. The improved vapor cell of claim 18, wherein the alkene-based material is derived from the Alpha Olefin Fraction C20-24.
